(19) United States
(12) Patent Application Publication
(10) Pub. No.: US 2004/0164222 A1
(43) Pub. Date: Aug. 26, 2004

(54) Systems and methods for providing multiple object planes in an optical image scanner

(76) Inventors: Rodney C. Harris, Fort Collins, CO (US); Kurt E. Spears, Fort Collins, CO (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/369,858

(22) Filed: Feb. 20, 2003

(51) Int. Cl. H01L 27/00

(52) U.S. Cl. 250/208.1

(57) ABSTRACT

Systems and methods for optically scanning multiple object planes are provided. One embodiment is a system for optical image scanning comprising a platen and an optical head for scanning. The optical head comprises a first lens array positioned to focus a first object plane at a first optical sensor array and a second lens array positioned to focus a second object plane at a second optical sensor array.

### BACKGROUND

Optical image scanners, also known as document scanners, convert a visible image (e.g., on a document or photograph, an image in a transparent medium, etc.) into an electronic form suitable for copying, storing, or processing by a computer. An optical image scanner may be a separate device, or an image scanner may be a part of a copier, part of a facsimile machine, or part of a multipurpose device. Reflective image scanners typically have a controlled source of light, and light is reflected off the surface of a document, through an optics system, and onto an array of photosensitive devices (e.g., a charge coupled-device, complimentary metal-oxide semiconductor (CMOS), etc.). Transparency image scanners pass light through a transparent image, for example a photographic positive slide, through optics, and then onto an array of photosensitive devices. The optics focus at least one line, called a scanline, of the image being scanned, onto the array of photosensitive devices. The photosensitive devices convert received light intensity into an electronic signal. An analog-to-digital converter converts the electronic signal into computer readable binary numbers, with each binary member representing an intensity value.

There are two common types of image scanners. In a first type, a single spherical reduction lens system is commonly used to focus the scanline onto the photosensor array, and the length of the photosensor array is much less than the length of the scanline. In a second type, an array of many lenses is used to focus the scanline onto the photosensor array, and the length of the photosensor array is the same length as the scanline. For the second type, it is common to use Selfoc® lens arrays (SLA) (available from Nippon Sheet Glass Co.), in which an array of rod-shaped lenses is used, typically with multiple photosensors receiving light through each individual lens.

Depth of focus refers to the maximum distance that the image position may be changed while maintaining a certain image resolution (i.e., the amount by which an object plane may be shifted along the optical path with respect to some reference plane and introduce no more than a specified acceptable blur). The depth of focus for lens arrays is typically relatively short in comparison to scanners using a single spherical reduction lens system. Typically, flat documents are forced by a cover against a transparent platen for scanning, so depth of focus is not a problem. However, there are some situations in which the surface being scanned cannot be placed directly onto a platen. One example is scanning 35 mm slides. A typical frame for a 35 mm slide holds the surface of the film about 0.7 to 1.5 mm above the surface of the platen. As a result, slides may be slightly out of focus when using lens arrays that are focused at the surface of the platen. Another example is scanning books or magazines where part of a page being scanned curves into a binding spline, causing part of the surface being scanned to be positioned above the transparent platen. A large depth of focus is needed to sharply image the binding spline.

### SUMMARY

Embodiments of the present invention provide systems and methods for optically scanning multiple object planes.

One embodiment is a system for optical image scanning comprising a platen and an optical head for scanning. The optical head comprises a first lens array positioned to focus a first object plane at a first optical sensor array and a second lens array positioned to focus a second object plane at a second optical sensor array.

Another embodiment is a method for providing multiple object planes in an optical image scanner. One such method comprises positioning an optical head a predetermined distance from a platen, focusing a first object plane located a first distance from the platen on a first optical sensor array, and focusing a second object plane located a second distance from the platen on a second optical sensor array

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a block diagram of a cross-sectional view of an optical image scanning environment in which the present invention may be implemented.

FIG. 2 is a block diagram of a cross-sectional view of another optical image scanning environment in which the present invention may be implemented.

FIG. 3 is a block diagram of a cross-sectional view of one embodiment of an optical image scanner according to the present invention for providing multiple object planes to be scanned.

FIG. 4 is a block diagram of a cross-sectional view of another embodiment of an optical image scanner according to the present invention for providing multiple object planes to be scanned.

### DETAILED DESCRIPTION

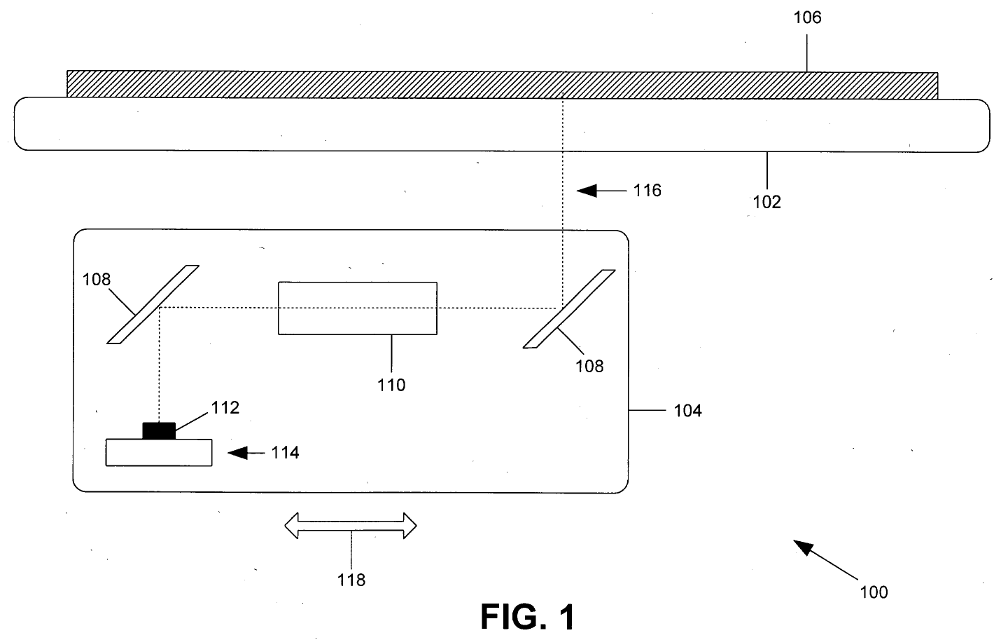

FIG. 1 is a block diagram of a cross-sectional view of an optical image scanning environment 100 in which the present invention may be implemented. The relative sizes of various objects in FIG. 1 are exaggerated to facilitate illustration. As shown in FIG. 1, optical image scanning environment 100 comprises an optical head 104 (also known as a carriage) positioned relative to a transparent platen 102. As known in the art, a document 106 may be placed on the top surface of the platen 102 for scanning. Optical scanning environment 100 may be included within an optical image scanner (e.g., a low profile flatbed scanner), a facsimile machine, copier, etc.

As further illustrated in FIG. 1, optical head 104 comprises a first reflective surface 108 (e.g., mirror, etc.), a lens array 110, a second reflective surface 108, and an image sensor module 114. Image sensor module 114 may comprise, for example, a printed circuit assembly or any other semiconductor device. Image sensor module 114 also includes a photosensor array 112, which may be any type of device configured to receive optical signals and convert the light intensity into an electronic signal. For example, as known in the art, photosensor array 112 may comprise a charge-coupled device (CCD), complimentary metal-oxide semiconductor (CMOS), etc.

Lens array 110 may comprise an array of rod-shaped lenses which have a relatively short depth of focus. For example, lens array 110 may comprise a Selfoc® lens array (SLA), which is manufactured and sold by Nippon Sheet Glass Co. of Somerset, N.J. A rod-lens array may comprise at least one row of graded-index micro lenses, which may be equal in dimensions and optical properties. The lenses may be aligned between two fiberglass-reinforced plastic (FRP) plates. Because FRP has a coefficient of thermal expansion equal to glass, thermal distortion and stress effects are minimal. The FRP also increases mechanical strength of the SLA. The interstices may be filled with black silicone to prevent flare (crosstalk) between the lenses and protect each individual lens.

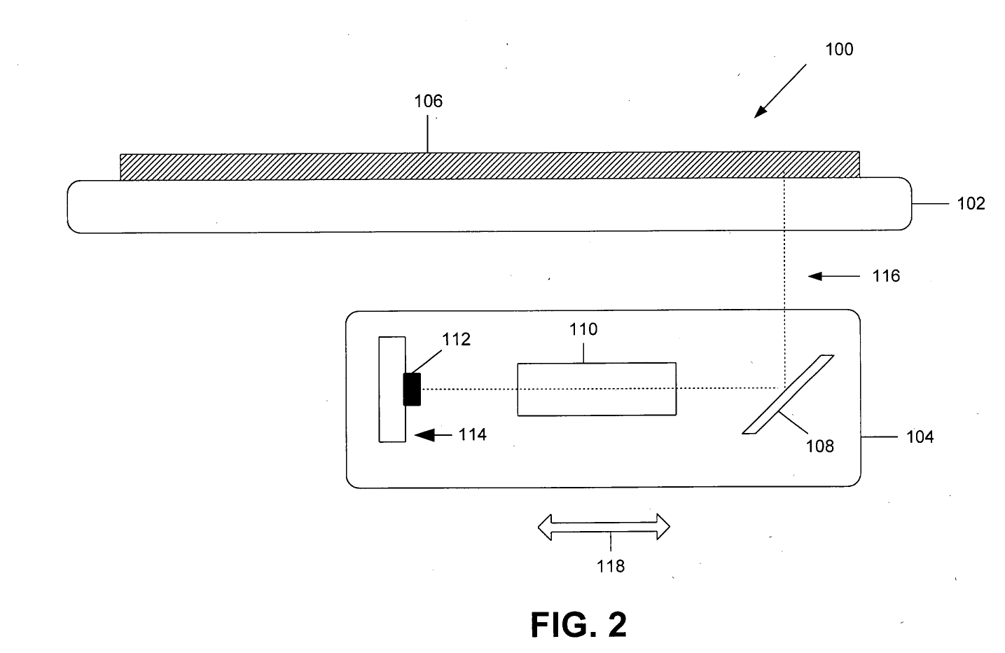

Referring again to FIG. 1, as a document 106 is being scanned by optical head 104, an optical signal 116 is reflected off the document 106 and towards the first reflective surface 108. The first reflective surface 108 directs the optical signal 116 through the lens array 110 to be focused. The optical signal 116 may also be reflected toward image sensor module 114 by a second reflective surface 108. The optical signal 116 is received by photosensor array 112 and converted into an electronic signal, which may be processed by an analog-to-digital converter, digital signal processor, etc. In this manner, the optics within optical head 104 focus a portion of an image of document 106 onto photosensor array 112. As illustrated in FIG. 2, the second reflective surface 108 may be optional. For instance, in order to alter the cross-sectional profile of optical head 104, second reflective surface 108 may be removed and the image sensor module 114 may be oriented perpendicular to the optical axis of lens array 110 to receive optical signal 116. Alternatively, the optical axis of lens array 110 may be oriented perpendicular to platen 102 to direct light through lens array 110 and onto photosensor array 112. The particular orientation of lens array 110 is not relevant to the present invention.

The optical components within optical head 104 focus at least one line (i.e., a scanline) of the image being scanned onto photosensor array 112. As known in the art, scanning of the entire image may be accomplished by translating optical head 104 relative to document 106 (e.g., by using cables) as indicated by reference number 118.

As mentioned above, due to the relatively small depth of focus of lens array 110, existing optical image scanners may produce blurred images of documents 106 that are positioned a small distance above the primary focal point of lens array 110. For example, existing optical image scanners may be configured with the primary focal point at a relatively short distance H₀ above the top surface of platen 102. When a document 106, such as a sheet of paper, etc. is positioned on platen 102, it may be located approximately the distance H₀ above the top surface of platen 102 or within the relatively small range of the depth of focus. However, if the document 106 is positioned at an object plane that is outside of a range of acceptable focus, existing optical image scanners may produce a blurred image. For instance, various types of documents (or portions of the document) may be located at an object plane outside of the range of acceptable focus when positioned on platen 102 (e.g., 35 mm slides, transparencies, photographs, books, magazines, etc.).

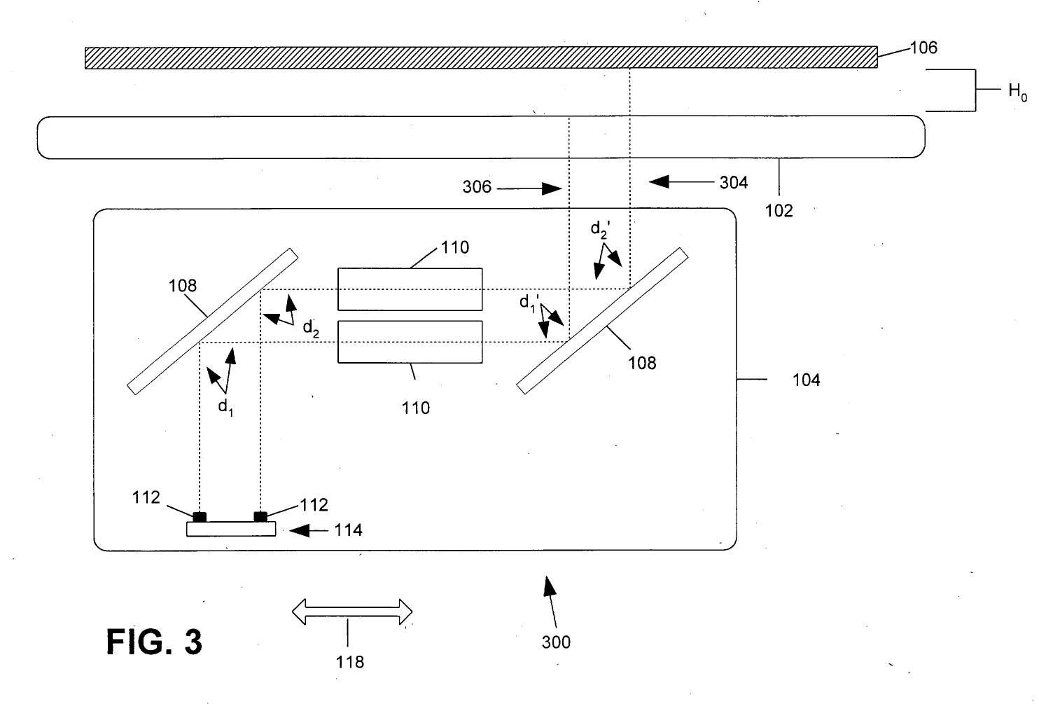

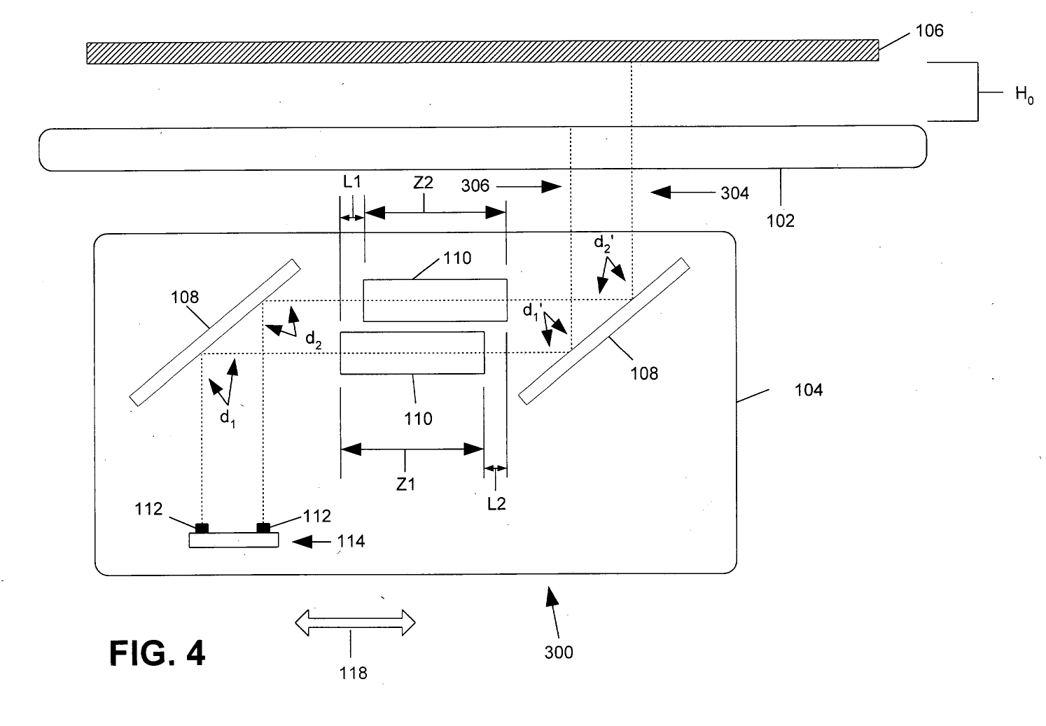

Having described a general overview of an optical image scanning environment in which the present invention may be implemented, various systems and methods according to the present invention for providing multiple object planes to be scanned will be described with respect to FIGS. 3 and 4. In general, the present invention provides a means for scanning an image at multiple object planes without having to reposition optical head 104 relative to platen 102. Instead of moving optical head 104, various embodiments of the present invention provide multiple object planes by modifying the internal optics of optical head 104. In this regard, optical head 104 may remain fixed relative to platen 102, while the internal optics are configured to provide multiple object planes (i.e., primary focal point at various distances above the top surface of platen 102). It should be appreciated, however, that in some embodiments of the present invention optical head 104 may also be repositioned to provide further flexibility in shifting object planes.

FIG. 3 is a block diagram of a cross-sectional view of one embodiment of an optical image scanner 300, according to the present invention, for providing multiple object planes to be scanned. Optical image scanner 300 comprises an optical head 104 positioned relative to a transparent platen 102. Furthermore, optical head 104 may comprise a first reflective surface 108 (e.g., mirror, etc.), at least two lens arrays 110, a second reflective surface 108, and an image sensor module 114, which comprises at least two photosensor arrays 112. As illustrated in FIG. 3, image sensor module 114 may be positioned in a parallel relationship to platen 102. Photosensor arrays 112 are disposed on the surface of image sensor module 114 so that one photosensor array 112 receives an optical signal (along optical path 306) corresponding to a first object plane located a first distance from platen 102 (e.g., near the top surface of platen 102) and another photosensor array 112 may receive an optical signal (along optical path 304) corresponding to a second object plane located a second distance from platen 102 (e.g., a distance H₀ away from the top surface of platen 102).

In general, optical image scanner 300 provides multiple object planes relative to platen 102 to be scanned by providing at least two lens arrays 110 and corresponding photosensor arrays 112. Each lens array 110 and corresponding photosensor array 112 (i.e., lens array 110/photosensor array 112 pair) are disposed in optical head 104 so that each photosensor array 112 is located at a unique object plane relative to platen 102. For example, referring to FIG. 3, one lens array 110 may be disposed in optical head 104 to focus an optical signal along path 306 (corresponding to an object plane located a distance H₀ from the top surface of platen 102) at a first photosensor array. A second lens array 110 may be disposed to focus an optical signal along optical path 304 (corresponding to an object plane located near the top surface of platen 102) at a second photosensor array. In this manner, the pair of photosensors 112/lens arrays 110 may simultaneously scan the multiple object planes.

During the scan process, a controlled source of light may be reflected off the surface of document 106, into optical head 104 through an aperture, and onto image sensor module 114. It should be appreciated that the pair of photosensors 112/lens arrays 110 enable optical signals from multiple object planes (e.g., optical path 306 and 304) to be focused, detected, and converted into electronic signals, etc. For example, if document 106 is a book, magazine, etc. where part of a page to be scanned curves into a binding spline, optical image scanner 300 may simultaneously scan each object plane and determine which object plane generates a more focused image. Therefore, as optical head 104 is translated relative to platen 102, more focused images may be generated as the object plane shifts along the curved spline.

It should be further appreciated that optical image scanner 300 may be configured in a number of ways to provide scanning of multiple object planes. For example, the pairs of lens arrays 110/photosensor arrays 112 may be disposed in a variety of ways to focus multiple object planes. In the embodiment illustrated in FIG. 3, lens arrays 110 may be arranged relative to each other so that the optical distances (d₁ and d₂) between each lens array 110/photosensor array 112 combination are equal. For instance, when viewed in cross-section as in FIG. 3, the lens arrays 110 may be positioned so that there is no offset along the optical axis (i.e., d₁=d₂). One lens array 110 may be configured with a focal length corresponding to one object plane and the other lens array 110 may be configured with a focal length corresponding to another object plane.

In one of a number of alternative embodiments, the lens arrays 110 may be configured with substantially the same focal properties (e.g., focal length, etc.). It should be appreciated that, where lens arrays 110 have substantially the same focal properties, one lens array 110 may be shifted a distance L1 relative to the other lens array along a common optical axis. For instance, when viewed in cross-section as in FIG. 4, the lens arrays 110 may be positioned so that there is an offset along the optical axis (i.e., d₁<d₂). It should be further appreciated that, due to the properties of lens arrays 110, the relative offset between the lens arrays 110 provides a shift in the relative object planes. In other words, the offset increases the distance between lens array 110 and photosensor array 112 (i.e., d₂=d₁+L1). Based on the properties of lens array 110, the increase in the distance between lens array 110 and photosensor array 112 translates into an equal increase in the distance between lens array 110 and the location of the corresponding object plane (i.e., d₂=d₂′) In this embodiment, it should be appreciated that the difference in object plane locations (H₀) will be twice as long as the offset (L1).

Therefore, one lens array 110 may focus an optical signal along path 306 (corresponding to an object plane located a distance H₀ from the top surface of platen 102) at a first photosensor array. A second lens array 110 may focus optical signal along path 304 (corresponding to an object plane located near the top surface of platen 102) at a second photosensor array. In this manner, the pair of photosensors 112/lens arrays 110 may simultaneously scan the multiple object planes.

The pair of lens arrays 110 need not have the same characteristics (e.g., dimensions, focal properties, etc.). For example, where different lens arrays 110 are used, the spatial variables shown in FIG. 4 may be designed for any configuration based on Equation 1.

TOTAL CONJUGATE 1=d₁+z₁+d′₁ (OPTICAL PATH 306)

TOTAL CONJUGATE 2=d₂+Z₂+d′₂ (OPTICAL PATH 304)

TOTAL CONJUGATE 1+H₀=TOTAL CONJUGATE 2 Equation 1

One of ordinary skill in the art will appreciate that optical image scanner 300 may be configured in a variety of ways. For example, the second reflective surface 108 may be removed and image sensor module 114 positioned to receive optical signals 404 and 406 without being reflected (FIG. 2). Additional reflective surfaces 108 may also be added to achieve the same function. Furthermore, reflective surfaces 108 may be removed and the lens arrays 10 disposed so that a common optical axis is perpendicular to the surface of platen 102.

Therefore, having thus described the invention, at least the following is claimed:

1. A system for optical image scanning, the system comprising:
a platen; and
an optical head for scanning, the optical head comprising:
a first lens array positioned to focus a first object plane at a first optical sensor array;
a second lens array positioned to focus a second object plane at a second optical sensor array.

2. The system of claim 1, wherein the first object plane is located a first distance from the platen and the second object plane is located a second distance from the platen.

3. The system of claim 1, wherein the lens arrays are configured with substantially the same focal properties.

4. The system of claim 3, wherein the first lens array is offset from the second lens array a predetermined distance along the optical axis.

5. The system of claim 1, wherein the first and second lens array have different focal lengths.

6. The system of claim 1, wherein the optical head further comprises an image sensor module comprising a first optical sensor array corresponding to the first lens array and a second optical sensor array corresponding to the second lens array.

7. The system of claim 6, wherein at least one of the first and second optical sensor arrays comprise a linear array of photosensitive devices.

8. The system of claim 6, wherein the first and second optical sensor arrays are configured to convert optical signals focused via the corresponding lens array into electrical signals.

9. A method for providing multiple object planes in an optical image scanner, the method comprising:
positioning an optical head a predetermined distance from a platen; focusing a first object plane located a first distance from the platen on a first optical sensor array; and
focusing a second object plane located a second distance from the platen on a second optical sensor array.

10. The method of claim 9, wherein the focusing a first object plane and focusing a second object plane involve different focal lengths.
